(19) United States
(12) Patent Application Publication
(10) Pub. No.: US 2026/0271611 A1
(43) Pub. Date: Sep. 10, 2026

(54) POLYAMIC ACID WITH SACRIFICIAL CARBOXYLIC ACID GROUPS AS PASSIVATORS FOR PEROVSKITES

(71) Applicant: City University of Hong Kong, Hong Kong (HK)

(72) Inventors: Shien-Ping FENG, Hong Kong (HK); Wei-Ting WANG, Hong Kong (HK)

(21) Appl. No.: 19/069,253

(22) Filed: Mar. 4, 2025

(51) Int. Cl. H10K 85/10; C08G 73/10; H10K 30/30; H10K 30/40; H10K 30/50; H10K 71/12; H10K 71/40

(52) U.S. Cl. CPC H10K 85/111; C08G 73/1082; H10K 30/30; H10K 30/40; H10K 30/50; H10K 71/12; H10K 71/40

(57) ABSTRACT

The present invention relates to a polyamic acid material containing sacrificial carboxylic acid groups, designed as a passivator to enhance the performance and stability of perovskite solar cells (PSCs). This material facilitates improved perovskite crystallization and passivator dispersion via weak interactions. During thermal treatment, the sacrificial carboxylic acid groups are eliminated, forming a hydrophobic polyimide protective layer that significantly improves water and chemical resistance. The polyamic acid-based approach addresses the challenges of degradation under heat and humidity, achieving a power conversion efficiency exceeding 23% while extending device lifespan. This innovation overcomes limitations in prior methods by integrating stability enhancement with high efficiency, marking a significant advancement in PSC technology and promoting their commercial viability.

### FIELD OF THE INVENTION

The present invention generally relates to at least the fields of perovskite solar cells, materials science, and electronic device fabrication.

### BACKGROUND OF THE INVENTION

Perovskite solar cells (PSCs) have garnered significant attention in recent years due to their high power conversion efficiency (PCE), which has surpassed 26%. Despite these impressive performance levels, the commercialization of PSCs is still hindered by their insufficient stability, particularly under harsh environmental conditions such as elevated temperature and humidity. The rapid degradation of perovskite materials in the presence of moisture and heat is a major challenge that limits their long-term operational viability, thereby impeding their widespread adoption in real-world applications.

Several approaches have been proposed in the field of perovskite solar cells to address these stability issues, particularly through the incorporation of passivators. These passivators are typically employed to enhance the crystallization of perovskite films, improve charge carrier dynamics, or create protective layers to mitigate degradation. One common approach involves the use of organic compounds that contain functional groups capable of interacting with perovskite materials to reduce defects and enhance their stability.

However, most of the existing methods present significant drawbacks. For instance, many passivators used in perovskite devices contain carboxylic acid groups that remain after processing. These residual carboxylic acid groups can cause hydrophilic behaviour at the grain boundaries or on the surface of the perovskite, leading to poor moisture resistance and diminishing the stability of the solar cells. Furthermore, Y U, Yang-Yen, et al.¹ and L U O, Huanting, et al.² demonstrate that several prior approaches for enhancing perovskite stability fail to involve high-temperature cyclization or thermal treatment, which is crucial for the removal of hydrophilic functional groups, leaving these groups intact in the final device. As a result, these strategies often fall short in achieving the desired combination of improved efficiency and enhanced stability.

### SUMMARY OF THE INVENTION

To address these limitations, the present invention introduces a polyamic acid material that contains sacrificial carboxylic acid groups. The carboxylic acid groups initially promote the dispersion of passivators or improving the crystallization of perovskite films.

In a first aspect, the present invention provides a polyamic acid-based passivator, wherein the polyamic acid-based passivator comprises a polyamic acid material with the following formula:

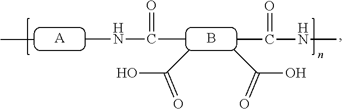

A is selected from

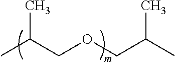

and m is in a range of 1 to 100,

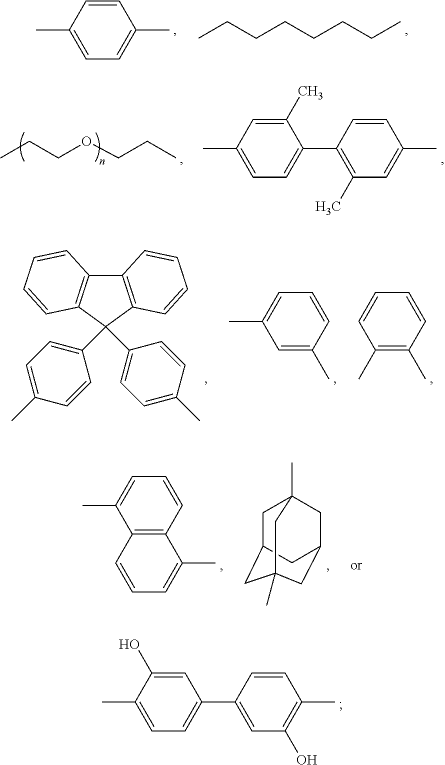

B is selected from

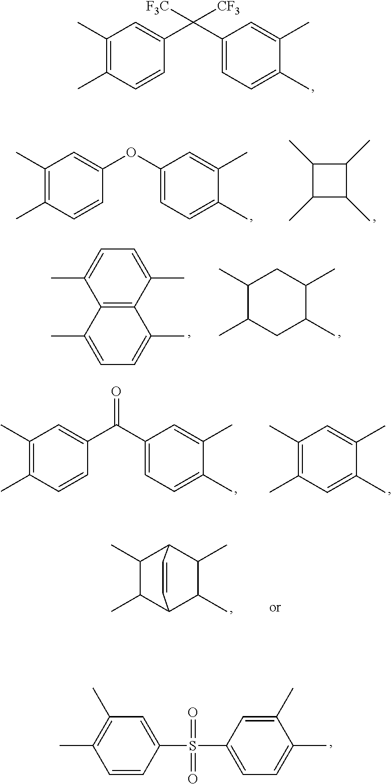

In one embodiment, the polyamic acid material undergoes thermal treatment to form a polyimide protective layer that enhances the stability of the perovskite.

In one embodiment, the polyamic acid material includes polymerizing poly(propylene oxide) diamine, 4,4′-(hexafluoroisopropylidene)diphthalic anhydride.

In one embodiment, the polyamic acid material is mixed with at least one other traditional passivator selected from the group consisting of n-butylammonium acetate, di-butylammonium bromide, di-butylammonium chloride, diphenylammonium chloride, di-propylammonium chloride, di-propylammonium iodide, butane-1,4-diammonium trifluoroacetate, di-butylammonium trifluoroacetate, diphenylammonium trifluoroacetate, di-propylammonium trifluoroacetate, 2-thiopheneethylammonium chloride, dimethylammonium trifluoroacetate, 2-thiopheneethylammonium iodide, di-propylammonium bromide, 4-chlorophenethylammonium iodide, diphenylammonium iodide, diphenylammonium bromide, 2-thiopheneethylammonium bromide, 4-chloro-phenethylammonium chloride, 4-chlorophenylammonium bromide, 4-hydroxyphenethylammonium bromide, 4-hydroxyphenethylammonium iodide, 1-n-hexyl-DABCO iodide, 1-naphthylammonium bromide, 2-naphthylammonium bromide, 1-naphthylammonium chloride, 2-naphthylammonium chloride, biphenylammonium bromide, biphenylammonium iodide, 2-furanemethylammonium chloride, 2-furanemethylammonium bromide, 2-furanemethylammonium iodide, ethylammonium chloride, ethylammonium formate, 4-chlorobenzylammonium chloride, 4-methylphenethylammonium chloride, 4-chlorobenzylammonium bromide, 4-methylphenethylammonium bromide, 4-methylphenethylammonium iodide, n-butylammonium tosylate, methylammonium mesylate, ethylammonium mesylate, n-butylammonium mesylate, formamidinium mesylate, 1,4-diazabicyclo[2.2.2]octane-1,4-diium chloride, piperazine-1,4-diium chloride, morpholinium chloride, 2-pyrrolidin-1-ium-1-ylethylammonium chloride, quinuclidin-1-ium chloride, pyrrolidinium chloride, trimethylammonium bromide, N,N-diethylethane-1,2-diammonium chloride, piperazine-1,4-diium bromide, tert-octylammonium chloride, tert-octylammonium bromide, neo-pentylammonium chloride, i-pentylammonium chloride, N,N-dimethylpropane-1,3-diammonium chloride, 4-chlorophenethylammonium bromide, N,N-diethylethane-1,2-diammonium bromide, morpholinium bromide, hexane-1,6-diammonium bromide, di-iso-propylammonium bromide, 2-methoxyethylammonium bromide, 2-methoxyethylammonium chloride, di-isopropylammonium chloride, N,N-diethylpropane-1,3-diammonium chloride, 2-pyrrolidin-1-ium-1-ylethylammonium bromide, imidazolium bromide, 1,4-diazabicyclo[2,2,2]octane-1,4-diium bromide, diethylammonium bromide, morpholinium iodide, 4-fluoro-phenethylammonium chloride, n-propylammonium bromide, piperazine hydroiodide, butane-1,4-diammonium bromide, ethane-1,2-diammonium bromide, n-octylammonium Bromide, n-pentylammonium bromide, n-pentylammonium chloride, 4-fluoro-phenylammonium bromide, n-octylammonium chloride, piperazine-1,4-diium iodide, 4-trifluoromethyl-phenylammonium bromide, 4-methoxy-phenethylammonium chloride, 4-methoxy-phenylammonium iodide, 4-methoxy-phenylammonium bromide, 4-trifluoromethyl-benzylammonium iodide, guanidinium bromide, N,N-dimethylpropane-1,3-diammonium iodide, N,N-dimethylethane-1,2-diammonium iodide, n-hexylammonium bromide, 4-trifluoromethyl-phenylammonium chloride, t-butylammonium bromide, quinuclidin-1-ium bromide, 2-methoxyethylammonium iodide, tert-octylammonium iodide, neo-pentylammonium bromide, n-dodecylammonium bromide, i-pentylammonium bromide, N,N-dimethylethane-1,2-diammonium bromide, cyclohexylmethylammonium bromide, phenethylammonium iodide, 4-fluoro-phenethylammonium bromide, n-butylammonium iodide, 1,4-diazabicyclo[2,2,2]octane-1,4-diium iodide, imidazolium iodide, iso-propylammonium bromide, iso-propylammonium iodide, pyrrolidinium bromide, quinuclidin-1-ium iodide, neo-pentylammonium iodide, cyclohexylammonium bromide, 4-trifluoromethyl-benzylammonium bromide, 4-trifluoromethyl-benzylammonium chloride, 4-trifluoromethyl-phenylammonium iodide, 4-fluoro-benzylammonium chloride, 4-methoxy-phenethylammonium bromide, acetamidinium bromide, 2-pyrrolidin-1-ium-1-ylethylammonium iodide, N,N-diethylpropane-1,3-diammonium iodide, N,N-diethylpropane-1,3-diammonium bromide, 4-fluoro-phenylammonium iodide, 4-fluoro-phenylammonium chloride, di-isopropylammonium trifluoroacetate, 2-methoxyethylammonium trifluoroacetate, iso-propylammonium trifluoroacetate, hexane-1,6-diammonium chloride, di-isopropylammonium iodide, hexane-1,6-diammonium iodide, ethylammonium iodide, n-hexylammonium iodide, pyrrolidinium thiocyanate, acetamidinium iodide, hexane-1,6-diammonium trifluoroacetate, ethylammonium trifluoroacetate, 4-fluoro-benzylammonium iodide, iso-pentylammonium iodide, pyridinium iodide, cyclohexylmethylammonium iodide, n-pentylammonium iodide, n-propylammonium trifluoroacetate, n-dodecylammonium iodide, cyclohexylammonium iodide, 4-fluoro-benzylammonium bromide, dimethylammonium bromide, benzylammonium iodide, t-butylammonium iodide, benzylammonium bromide, 4-fluoro-phenethylammonium iodide, 4-methoxy-phenethylammonium iodide, n-butylammonium bromide, ethane-1,2-diammonium iodide, n-octylammonium Iodide, phenethylammonium bromide, butane-1,4-diammonium iodide, piperazine hydroiodide, or a combination thereof.

In one embodiment, the polyamic acid material further contains an ether group that acts as a hydrogen bond acceptor.

In another aspect, the present invention provides a perovskite solar cell, which includes, from top to bottom: a metal electrode layer; an electron transport layer (ETL); a perovskite layer; a hole transport layer (HTL) and a transparent conductive layer. The perovskite layer includes a perovskite precursor composition and at least one polyamic acid-based passivator. The at least one polyamic acid-based passivator comprises a polyamic acid material containing sacrificial carboxylic acid groups. It is incorporated into the perovskite precursor solution, which is then coated onto a substrate, or alternatively, it can be deposited on one or both sides of the pristine perovskite layer.

The polyamic acid material interacts with the perovskite components between the sacrificial carboxylic acid groups and the perovskite. The polyamic acid material undergoes thermal treatment to form a polyimide protective layer on the perovskite layer.

The polyamic acid can be used as a passivator and incorporated into the perovskite precursor solution, where it interacts with the ions and improves the crystallinity of the perovskite. After perovskite formation, the polyamic acid material fixed at the grain boundaries or on the perovskite surface. Upon thermal treatment, it undergoes cyclization to form polyimide, which helps inhibit perovskite degradation.

In another embodiment, the polyamic acid material can be used either alone as a passivator or mixing with other passivators, and its coating on the perovskite surface can passivate ionic defects in the perovskite. The at least one other passivator selected from the group consisting of n-butylammonium acetate, di-butylammonium bromide, diphenylammonium chloride, piperazine hydroiodide, or a combination thereof.

In one embodiment, the polyamic acid material is present in the perovskite precursor composition at a concentration of 0.1-10 mg/ml.

In one embodiment, the polyamic acid material or the polyamic acid-based passivator includes poly(propylene oxide) diamine and 4,4′-(hexafluoroisopropylidene)diphthalic anhydride.

In one embodiment, the passivation layer has a thickness between 0.1 nm and 25 nm.

In one embodiment, the polyamic acid material in the at least one polyamic acid-based passivator enhances the crystallization of the perovskite.

In another embodiment, the sacrificial carboxylic acid groups in the polyamic acid assist in the dispersion of the polyamic acid-based passivator.

In one embodiment, the electron transport layer is selected from a material comprising SnO₂, TiO₂, PCBM/bathocuproine (BCP), C₆₀/bathocuproine or a mixture thereof.

In one embodiment, the hole transport layer is selected from spiro-OMeTAD, PTAA, NiO_{X}, self-assembled monolayers (e.g. (2-(9H-carbazol-9-yl)ethyl)phosphonic acid, CbzNaph), or an organic hole transport material.

In one embodiment, the polyimide protective layer is formed after thermal treatment at a temperature of 100-150° C., enhancing the hydrophobic properties of the perovskite, and the polyimide protective layer is heat-, water- and chemical-resistant. Thermal treatment results in the dehydration of the sacrificial carboxylic acid groups, forming a hydrophobic polyimide layer.

In one embodiment, the perovskite solar cell achieves an improvement in power conversion efficiency of at least 23%.

In another aspect, the present invention provides a perovskite solar cell, which includes, from top to bottom: a metal electrode layer, a hole transport layer, a perovskite layer, an electron transport layer and a transparent conductive layer. The perovskite layer includes a perovskite precursor composition and at least one polyamic acid-based passivator.

The at least one polyamic acid-based passivator comprises a polyamic acid material containing sacrificial carboxylic acid groups. It is incorporated into the perovskite precursor solution, which is then coated onto a substrate, or alternatively, it can be deposited on one or both sides of the pristine perovskite layer.

The polyamic acid material interacts with the perovskite components between the sacrificial carboxylic acid groups and the perovskite. The polyamic acid material undergoes thermal treatment to form a polyimide protective layer on the perovskite layer.

In one embodiment, the polyamic acid material or the polyamic acid-based passivator includes poly(propylene oxide) diamine and 4,4′-(hexafluoroisopropylidene)diphthalic anhydride.

In another embodiment, the polyamic acid-based passivator is further mixed with at least one other traditional passivator selected from the group consisting of n-butylammonium acetate, di-butylammonium bromide, di-butylammonium chloride, diphenylammonium chloride, di-propylammonium chloride, di-propylammonium iodide, butane-1,4-diammonium trifluoroacetate, di-butylammonium trifluoroacetate, diphenylammonium trifluoroacetate, di-propylammonium trifluoroacetate, 2-thiopheneethylammonium chloride, dimethylammonium trifluoroacetate, 2-thiopheneethylammonium iodide, di-propylammonium bromide, 4-chlorophenethylammonium iodide, diphenylammonium iodide, diphenylammonium bromide, 2-thiopheneethylammonium bromide, 4-chloro-phenethylammonium chloride, 4-chlorophenylammonium bromide, 4-hydroxyphenethylammonium bromide, 4-hydroxyphenethylammonium iodide, 1-n-hexyl-DABCO iodide, 1-naphthylammonium bromide, 2-naphthylammonium bromide, 1-naphthylammonium chloride, 2-naphthylammonium chloride, biphenylammonium bromide, biphenylammonium iodide, 2-furanemethylammonium chloride, 2-furanemethylammonium bromide, 2-furanemethylammonium iodide, ethylammonium chloride, ethylammonium formate, 4-chlorobenzylammonium chloride, 4-methylphenethylammonium chloride, 4-chlorobenzylammonium bromide, 4-methylphenethylammonium bromide, 4-methylphenethylammonium iodide, n-butylammonium tosylate, methylammonium mesylate, ethylammonium mesylate, n-butylammonium mesylate, formamidinium mesylate, 1,4-diazabicyclo[2.2.2]octane-1,4-diium chloride, piperazine-1,4-diium chloride, morpholinium chloride, 2-pyrrolidin-1-ium-1-ylethylammonium chloride, quinuclidin-1-ium chloride, pyrrolidinium chloride, trimethylammonium bromide, N,N-diethylethane-1,2-diammonium chloride, piperazine-1,4-diium bromide, tert-octylammonium chloride, tert-octylammonium bromide, neo-pentylammonium chloride, i-pentylammonium chloride, N,N-dimethylpropane-1,3-diammonium chloride, 4-chlorophenethylammonium bromide, N,N-diethylethane-1,2-diammonium bromide, morpholinium bromide, hexane-1,6-diammonium bromide, di-iso-propylammonium bromide, 2-methoxyethylammonium bromide, 2-methoxyethylammonium chloride, di-isopropylammonium chloride, N,N-diethylpropane-1,3-diammonium chloride, 2-pyrrolidin-1-ium-1-ylethylammonium bromide, imidazolium bromide, 1,4-diazabicyclo[2,2,2]octane-1,4-diium bromide, diethylammonium bromide, morpholinium iodide, 4-fluoro-phenethylammonium chloride, n-propylammonium bromide, piperazine hydroiodide, butane-1,4-diammonium bromide, ethane-1,2-diammonium bromide, n-octylammonium Bromide, n-pentylammonium bromide, n-pentylammonium chloride, 4-fluoro-phenylammonium bromide, n-octylammonium chloride, piperazine-1,4-diium iodide, 4-trifluoromethyl-phenylammonium bromide, 4-methoxy-phenethylammonium chloride, 4-methoxy-phenylammonium iodide, 4-methoxy-phenylammonium bromide, 4-trifluoromethyl-benzylammonium iodide, guanidinium bromide, N,N-dimethylpropane-1,3-diammonium iodide, N,N-dimethylethane-1,2-diammonium iodide, n-hexylammonium bromide, 4-trifluoromethyl-phenylammonium chloride, t-butylammonium bromide, quinuclidin-1-ium bromide, 2-methoxyethylammonium iodide, tert-octylammonium iodide, neo-pentylammonium bromide, n-dodecylammonium bromide, i-pentylammonium bromide, N,N-dimethylethane-1,2-diammonium bromide, cyclohexylmethylammonium bromide, phenethylammonium iodide, 4-fluoro-phenethylammonium bromide, n-butylammonium iodide, 1,4-diazabicyclo[2,2,2]octane-1,4-diium iodide, imidazolium iodide, iso-propylammonium bromide, iso-propylammonium iodide, pyrrolidinium bromide, quinuclidin-1-ium iodide, neo-pentylammonium iodide, cyclohexylammonium bromide, 4-trifluoromethyl-benzylammonium bromide, 4-trifluoromethyl-benzylammonium chloride, 4-trifluoromethyl-phenylammonium iodide, 4-fluoro-benzylammonium chloride, 4-methoxy-phenethylammonium bromide, acetamidinium bromide, 2-pyrrolidin-1-ium-1-ylethylammonium iodide, N,N-diethylpropane-1,3-diammonium iodide, N,N-diethylpropane-1,3-diammonium bromide, 4-fluoro-phenylammonium iodide, 4-fluoro-phenylammonium chloride, di-isopropylammonium trifluoroacetate, 2-methoxyethylammonium trifluoroacetate, iso-propylammonium trifluoroacetate, hexane-1,6-diammonium chloride, di-isopropylammonium iodide, hexane-1,6-diammonium iodide, ethylammonium iodide, n-hexylammonium iodide, pyrrolidinium thiocyanate, acetamidinium iodide, hexane-1,6-diammonium trifluoroacetate, ethylammonium trifluoroacetate, 4-fluoro-benzylammonium iodide, iso-pentylammonium iodide, pyridinium iodide, cyclohexylmethylammonium iodide, n-pentylammonium iodide, n-propylammonium trifluoroacetate, n-dodecylammonium iodide, cyclohexylammonium iodide, 4-fluoro-benzylammonium bromide, dimethylammonium bromide, benzylammonium iodide, t-butylammonium iodide, benzylammonium bromide, 4-fluoro-phenethylammonium iodide, 4-methoxy-phenethylammonium iodide, n-butylammonium bromide, ethane-1,2-diammonium iodide, n-octylammonium Iodide, phenethylammonium bromide, butane-1,4-diammonium iodide, piperazine hydroiodide, or a combination thereof.

The present invention addresses the existing technical challenges in perovskite solar cell technology by offering a passivator based on polyamic acid that improves both the efficiency and stability of perovskite devices, making it a significant advancement in the field of solar energy.

This innovative approach overcomes the drawbacks of prior art by providing a stable and efficient solution that not only enhances the performance of perovskite solar cells but also significantly extends their operational lifespan.

### BRIEF DESCRIPTION OF THE DRAWINGS

Embodiments of the invention are described in more details hereinafter with reference to the drawings, in which:

FIG. 1 shows ¹H NMR of polyamic acid prepared by poly(propylene oxide) diamine and 4,4′-(hexafluoroisopropylidene) diphthalic anhydride in according to one embodiment of the present invention;

FIG. 2 shows a schematic diagram of imidization of polyamic acid after annealing;

FIG. 3 shows a schematic diagram of a chemical reaction of polyamic acid using as passivator;

FIG. 4 shows a schematic diagram of a chemical reaction of passivator using as additive in perovskite precursor;

FIGS. 5A-5C show conventional device structures using polyamic acid-based passivators in according to one embodiment of the present invention. FIGS. 5D-5F show inverted device structures using polyamic acid-based passivators in according to one embodiment of the present invention;

FIG. 6 shows a photograph of perovskite films with and without polyamic acid aged at 85° C. and 85% relative humidity;

FIG. 7 shows J-V curves of device with and without polyamic acid.

### DETAILED DESCRIPTION

Despite the power conversion efficiency of perovskite solar cells surpassing 26%, their limited stability continues to be a significant challenge preventing commercialization. To tackle this problem, the present invention introduces a polyamic acid material containing sacrificial carboxylic acid groups, which can serve as a passivator for perovskites.

Polyamic acid is the precursor of polyimide polymers. When the polyamic acid material is incorporated as an additive in the perovskite composition, the sacrificial carboxylic acid groups can function as hydrogen bond donors, interacting with the perovskite components.

Upon thermal treatment during the later stages of fabrication, these sacrificial carboxylic acid groups undergoes dehydration, resulting in a hydrophobic polyimide-based protective layer. This transformation significantly enhances the formation of heat-, water- and chemical-resistant perovskite, thereby improving its long-term stability without compromising its performance.

The chemical structure of the of the polyamic acid-based passivator is shown as Formula (I):

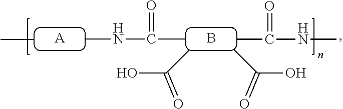

A is selected from

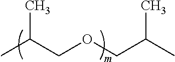

and m is selected from 1 to 100,

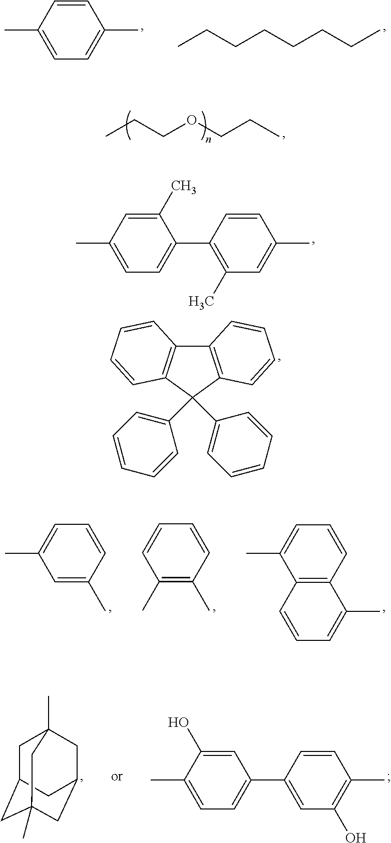

B is selected from

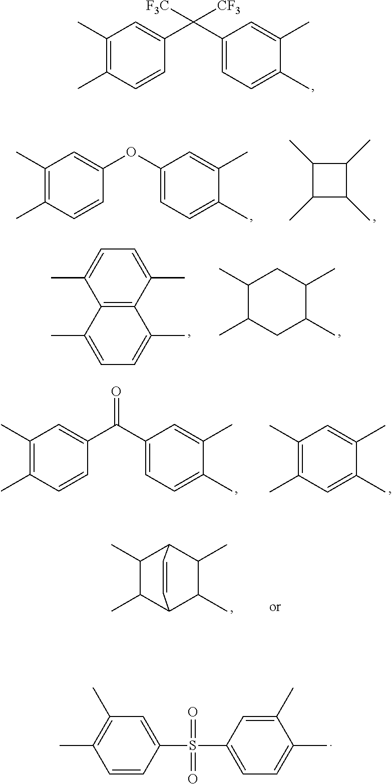

When the polyamic acid material is used as a passivator, the sacrificial carboxylic acid groups can assist in the dispersion of other passivators, enhancing the passivation effect.

In one embodiment, the chemical structure of the of the polyamic acid-based passivator is shown as Formula (II):

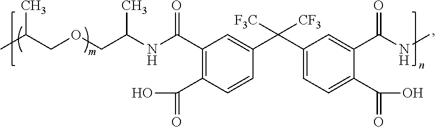

where n is number of repeating units of polymer, and m is in a range of 1-100.

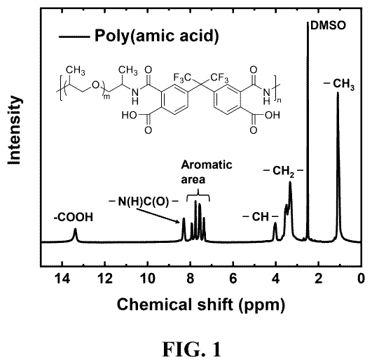

FIG. 1 presents the proton nuclear magnetic resonance (¹H NMR) spectra of Formula (II), where the polyamic acid is prepared by the polymerization of poly(propylene oxide) diamine and 4,4′-(hexafluoroisopropylidene)diphthalic anhydride. The spectrum is recorded in deuterated dimethyl sulfoxide (DMSO-d₆) as the solvent. The characteristic chemical shifts corresponding to various proton environments within the polyamic acid structure are labelled on the spectrum. A peak is observed in the region of 12-14 ppm, assigned to the carboxyl (—COOH) proton in the polyamic acid backbone. Peaks in the range of 7-9 ppm correspond to the aromatic protons from the benzene rings in the 4,4′-(hexafluoroisopropylidene)diphthalic anhydride unit and amide protons (N—H) in the polyamic acid backbone. Peaks between 1-5 ppm are assigned to the aliphatic protons from the poly(propylene oxide) backbone, including the —CH— and —CH₂— groups. A distinct peak around 1 ppm corresponds to the terminal methyl groups of the poly(propylene oxide) segment. A sharp peak at approximately 2.5 ppm corresponds to the residual DMSO solvent.

The spectrum confirms the successful polymerization of poly(propylene oxide) diamine with 4,4′-(hexafluoroisopropylidene)diphthalic anhydride, as evidenced by the presence of carboxyl, amide, aromatic, and aliphatic proton signals consistent with the polyamic acid structure of Formula (II). The aromatic region further verifies the incorporation of the diphthalic anhydride moiety, while the aliphatic and methyl peaks confirm the poly(propylene oxide) segments.

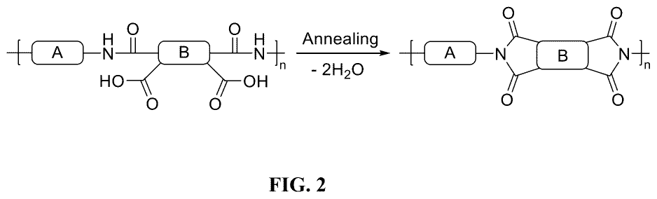

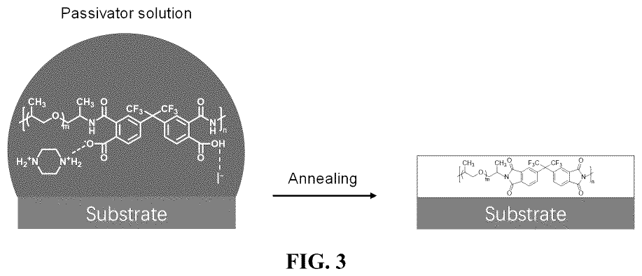

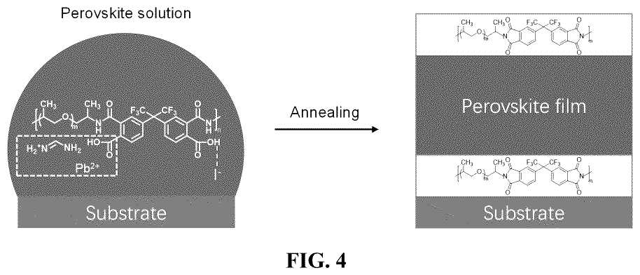

When the polyamic acid is prepared by poly(propylene oxide) diamine and 4,4′-(hexafluoroisopropylidene)diphthalic anhydride, the ether groups in the polyamic acid polymer can act as hydrogen bond acceptors, while the carboxylic acid groups serve as hydrogen bond donors. When this polyamic acid or its mixture with other passivator is used as a passivator, the polyamic acid can interact with other passivator (such as piperazine hydroiodide) via acid-base neutralization reaction or hydrogen bonding, enhancing the dispersion of the passivator (FIG. 3). Upon subsequent thermal treatment, it undergoes dehydration and imidization reaction to form polyimide, as shown in FIG. 2. The polyamic acid undergoes cyclization to form polyimide (FIGS. 2-3). When the polyamic acid passivator is added as an additive to the perovskite composition, it interacts with the ions. After the formation of the perovskite, the polyamic acid material fixes at the grain boundaries or on the surface of the perovskite, and upon thermal treatment, it undergoes cyclization to form polyimide, as shown in FIG. 4.

In another embodiment, the polyamic acid-based passivators can be mixed with at least one other traditional passivator. Examples of the at least one other traditional passivator may include n-butylammonium acetate, di-butylammonium bromide, di-butylammonium chloride, diphenylammonium chloride, di-propylammonium chloride, di-propylammonium iodide, butane-1,4-diammonium trifluoroacetate, di-butylammonium trifluoroacetate, diphenylammonium trifluoroacetate, di-propylammonium trifluoroacetate, 2-thiopheneethylammonium chloride, dimethylammonium trifluoroacetate, 2-thiopheneethylammonium iodide, di-propylammonium bromide, 4-chlorophenethylammonium iodide, diphenylammonium iodide, diphenylammonium bromide, 2-thiopheneethylammonium bromide, 4-chloro-phenethylammonium chloride, 4-chlorophenylammonium bromide, 4-hydroxyphenethylammonium bromide, 4-hydroxyphenethylammonium iodide, 1-n-hexyl-DABCO iodide, 1-naphthylammonium bromide, 2-naphthylammonium bromide, 1-naphthylammonium chloride, 2-naphthylammonium chloride, biphenylammonium bromide, biphenylammonium iodide, 2-furanemethylammonium chloride, 2-furanemethylammonium bromide, 2-furanemethylammonium iodide, ethylammonium chloride, ethylammonium formate, 4-chlorobenzylammonium chloride, 4-methylphenethylammonium chloride, 4-chlorobenzylammonium bromide, 4-methylphenethylammonium bromide, 4-methylphenethylammonium iodide, n-butylammonium tosylate, methylammonium mesylate, ethylammonium mesylate, n-butylammonium mesylate, formamidinium mesylate, 1,4-diazabicyclo[2.2.2]octane-1,4-diium chloride, piperazine-1,4-diium chloride, morpholinium chloride, 2-pyrrolidin-1-ium-1-ylethylammonium chloride, quinuclidin-1-ium chloride, pyrrolidinium chloride, trimethylammonium bromide, N,N-diethylethane-1,2-diammonium chloride, piperazine-1,4-diium bromide, tert-octylammonium chloride, tert-octylammonium bromide, neo-pentylammonium chloride, i-pentylammonium chloride, N,N-dimethylpropane-1,3-diammonium chloride, 4-chlorophenethylammonium bromide, N,N-diethylethane-1,2-diammonium bromide, morpholinium bromide, hexane-1,6-diammonium bromide, di-iso-propylammonium bromide, 2-methoxyethylammonium bromide, 2-methoxyethylammonium chloride, di-isopropylammonium chloride, N,N-diethylpropane-1,3-diammonium chloride, 2-pyrrolidin-1-ium-1-ylethylammonium bromide, imidazolium bromide, 1,4-diazabicyclo[2,2,2]octane-1,4-diium bromide, diethylammonium bromide, morpholinium iodide, 4-fluoro-phenethylammonium chloride, n-propylammonium bromide, piperazine hydroiodide, butane-1,4-diammonium bromide, ethane-1,2-diammonium bromide, n-octylammonium Bromide, n-pentylammonium bromide, n-pentylammonium chloride, 4-fluoro-phenylammonium bromide, n-octylammonium chloride, piperazine-1,4-diium iodide, 4-trifluoromethyl-phenylammonium bromide, 4-methoxy-phenethylammonium chloride, 4-methoxy-phenylammonium iodide, 4-methoxy-phenylammonium bromide, 4-trifluoromethyl-benzylammonium iodide, guanidinium bromide, N,N-dimethylpropane-1,3-diammonium iodide, N,N-dimethylethane-1,2-diammonium iodide, n-hexylammonium bromide, 4-trifluoromethyl-phenylammonium chloride, t-butylammonium bromide, quinuclidin-1-ium bromide, 2-methoxyethylammonium iodide, tert-octylammonium iodide, neo-pentylammonium bromide, n-dodecylammonium bromide, i-pentylammonium bromide, N,N-dimethylethane-1,2-diammonium bromide, cyclohexylmethylammonium bromide, phenethylammonium iodide, 4-fluoro-phenethylammonium bromide, n-butylammonium iodide, 1,4-diazabicyclo[2,2,2]octane-1,4-diium iodide, imidazolium iodide, iso-propylammonium bromide, iso-propylammonium iodide, pyrrolidinium bromide, quinuclidin-1-ium iodide, neo-pentylammonium iodide, cyclohexylammonium bromide, 4-trifluoromethyl-benzylammonium bromide, 4-trifluoromethyl-benzylammonium chloride, 4-trifluoromethyl-phenylammonium iodide, 4-fluoro-benzylammonium chloride, 4-methoxy-phenethylammonium bromide, acetamidinium bromide, 2-pyrrolidin-1-ium-1-ylethylammonium iodide, N,N-diethylpropane-1,3-diammonium iodide, N,N-diethylpropane-1,3-diammonium bromide, 4-fluoro-phenylammonium iodide, 4-fluoro-phenylammonium chloride, di-isopropylammonium trifluoroacetate, 2-methoxyethylammonium trifluoroacetate, iso-propylammonium trifluoroacetate, hexane-1,6-diammonium chloride, di-isopropylammonium iodide, hexane-1,6-diammonium iodide, ethylammonium iodide, n-hexylammonium iodide, pyrrolidinium thiocyanate, acetamidinium iodide, hexane-1,6-diammonium trifluoroacetate, ethylammonium trifluoroacetate, 4-fluoro-benzylammonium iodide, iso-pentylammonium iodide, pyridinium iodide, cyclohexylmethylammonium iodide, n-pentylammonium iodide, n-propylammonium trifluoroacetate, n-dodecylammonium iodide, cyclohexylammonium iodide, 4-fluoro-benzylammonium bromide, dimethylammonium bromide, benzylammonium iodide, t-butylammonium iodide, benzylammonium bromide, 4-fluoro-phenethylammonium iodide, 4-methoxy-phenethylammonium iodide, n-butylammonium bromide, ethane-1,2-diammonium iodide, n-octylammonium Iodide, phenethylammonium bromide, butane-1,4-diammonium iodide, piperazine hydroiodide, or a combination thereof.

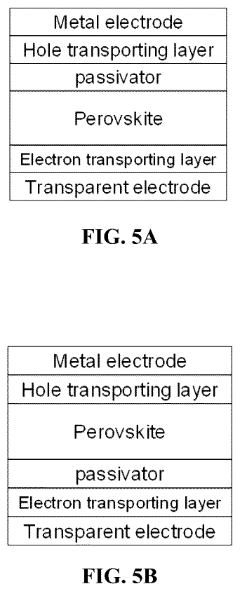

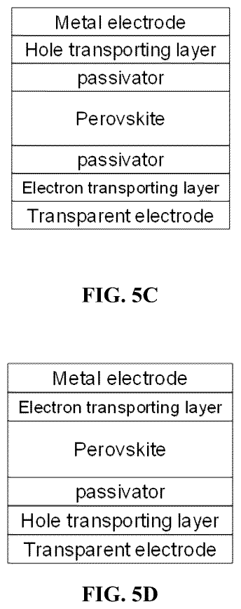

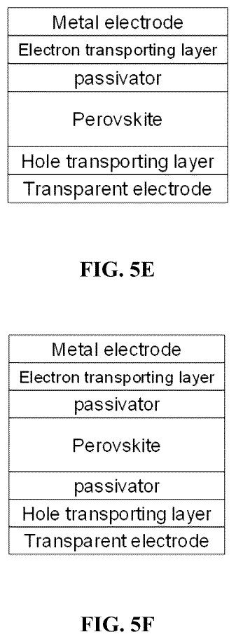

In another aspect, the present invention provides a perovskite solar cell structured in the following order: a transparent conductive layer; an electron transport layer (ETL); a perovskite layer; a hole transport layer (HTL) and a metal electrode layer. The perovskite layer includes a perovskite precursor composition and at least one polyamic acid-based passivator. The at least one polyamic acid-based passivator is deposited on one side or both sides of the perovskite (FIGS. 5A-5C). Alternatively, the polyamic acid material can be used either alone as a passivator, or mixing with other traditional passivators.

In another aspect, the present invention provides a perovskite solar cell structured in the following order: a transparent conductive layer; a hole transport layer (HTL); a perovskite layer; an electron transport layer (ETL) and a metal electrode layer (FIGS. 5D-5F).

In another aspect, the present invention provides a method for incorporating polyamic acid into perovskite devices, which can be carried out using one of the following two approaches:
(1) Incorporation of polyamic acid passivator into the perovskite precursor solution: Polyamic acid, or a mixture of polyamic acid and other passivators, is mixed into the perovskite precursor solution at a concentration ranging from 0.1 to 10 mg/mL. This concentration allows for effective integration of polyamic acid into the perovskite matrix, enhancing its film-forming properties. The resulting mixture is then deposited onto a substrate, typically using spin-coating, doctor-blading, or other suitable deposition techniques. The film is annealed at a temperature between 100° C. and 150° C. for a period of 1 to 10 minutes, which promotes the desired crystallization of the perovskite material while also activating the polyamic acid for optimal performance. The polyamic acid's role in this approach is to improve the homogeneity and stability of the perovskite layer, which contributes to the improved efficiency and durability of the device.
(2) Coating the perovskite film with polyamic acid passivator on one or both sides: Polyamic acid, or a mixture of polyamic acid and other passivators, is applied as a passivating layer on the surface of the perovskite film or on the charge transporting layers. The passivator can be deposited using solution-based techniques such as spin-coating, drop-casting, or vapor deposition. The passivation process helps to reduce surface trap states and minimize charge recombination, thereby improving the overall stability and efficiency of the perovskite device. After deposition, the film is annealed at a temperature between 100° C. and 150° C. for 1 to 10 minutes, which ensures imidization of the passivating layer. The passivation with polyamic acid improves the long-term stability of the device, particularly under harsh environmental conditions such as humidity and temperature fluctuations.

These methods are effective in enhancing the performance, stability, and longevity of perovskite devices, making them suitable for commercial applications in solar cells, light-emitting devices, and other optoelectronic devices.

In another aspect, the present invention provides a method of passivating a perovskite film, including the steps of
(1) Preparation of the passivating solution: dissolve the polyamic acid material in a suitable solvent (e.g., isopropyl alcohol (IPA)), to form a passivating solution at a concentration of 0.1-10 mg/mL. Optionally, the solution may include additional passivators, such as piperazine hydroiodide or n-butylammonium acetate, to enhance passivation effects.
(2) Application of the passivating solution: coat the passivating solution onto the surface of the pre-formed perovskite film using a solution deposition technique such as spin-coating, drop-casting, or spray-coating. For spin-coating, the rotation speed is set to 1000-5000 rpm, ensuring uniform coverage across the film.
(3) Aging treatment: heat the coated perovskite film at a temperature ranging from 100° C. to 150° C. This step induces cyclization to form a polyimide layer. The resulting polyimide layer passivates the grain boundaries and surface of the perovskite film, providing enhanced heat, moisture and chemical resistance.

### EXAMPLE

### Example 1

### Preparation of Polyamic Acid-Based Passivator

In this example, a polyamic acid material is synthesized by polymerizing poly(propylene oxide) diamine and 4,4′-(hexafluoroisopropylidene)diphthalic anhydride. The molar ratio of the diamine to anhydride is 1:1. The reaction is carried out at a temperature of 25° C. for 6 hours. The resulting polymer is then precipitated, washed, and vacuum-dried at 25° C. for 8 hours.

### Example 2

### Fabrication and Performance of PSCs

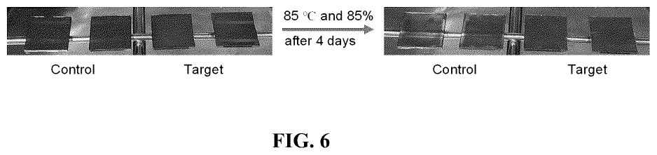

Referring to FIG. 6, when polyamic acid is used as a passivator and coated onto the surface of the perovskite film, it significantly enhances the stability of the perovskite film. After aging for approximately 4 days at 85° C. and 85% relative humidity, the pristine perovskite film exhibits significant surface degradation, whereas the perovskite film containing polyamic acid remains intact.

The inverted PSC is assembled with the following structure: ITO/[2-(9H-carbazol-9-yl)ethyl]phosphonic acid (2PACz)/perovskite mixed with polyamic acid/fullerene (C₆₀)/bathocuproine (BCP)/Au. In this configuration, polyamic acid passivator is incorporated into the perovskite precursor solution as an additive. The inclusion of polyamic acid passivator enhances the power conversion efficiency of the device, increasing from 21.4% to 23.2%.

In addition, another inverted PSC is assembled with the following structure: ITO/2PACz/perovskite/polyamic acid/fullerene (C₆₀)/BCP/Au. In this configuration, polyamic acid is applied as a passivating layer on the surface of the perovskite film. This passivation treatment improves the power conversion efficiency of the solar cell, increasing it from 21.4% to 23.1%.

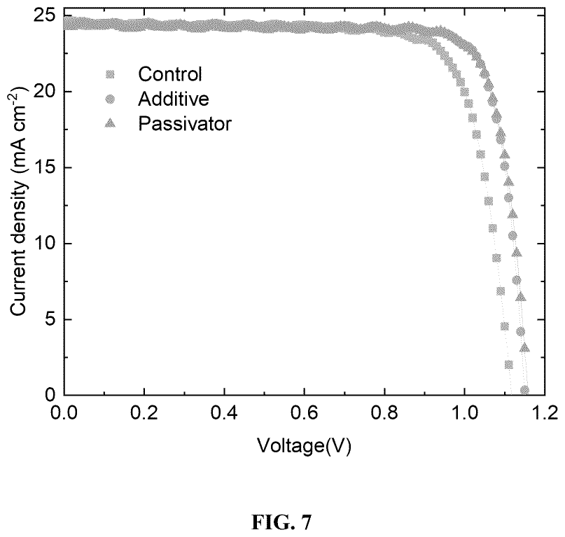

Both results are shown in FIG. 7 and summarized in Table 1.

TABLE 1
Summary of photovoltaic parameters of the perovskite solar cells

| Sample | J_{SC} (mA cm⁻²) | V_{OC} (V) | FF | PCE (%) |
|---|---|---|---|---|
| Control | 24.6 | 1.12 | 0.78 | 21.4 |
| Passivator in perovskite | 24.4 | 1.15 | 0.83 | 23.2 |
| precursor (additive) | | | | |
| Passivator | 24.3 | 1.16 | 0.82 | 23.1 |

In conclusion, the present invention provides a polyamic acid material that contains sacrificial carboxylic acid groups. The carboxylic groups can initially participate in improving perovskite crystallization or assisting in the dispersion of passivators through acid-base neutralization or hydrogen bonding interactions before thermal treatment. After thermal treatment, the polyamic acid undergoes imidization, resulting in the formation of a hydrophobic polyimide that protects the perovskite. This process not only improves the efficiency of the perovskite but also prolongs its stability.

The foregoing description of the present invention has been provided for the purposes of illustration and description. It is not intended to be exhaustive or to limit the invention to the precise forms disclosed. Many modifications and variations will be apparent to the practitioner skilled in the art.

The embodiments are chosen and described in order to best explain the principles of the invention and its practical application, thereby enabling others skilled in the art to understand the invention for various embodiments and with various modifications that are suited to the particular use contemplated.

### Definition

Throughout this specification, unless the context requires otherwise, the word “comprise” or variations such as “comprises” or “comprising”, will be understood to imply the inclusion of a stated integer or group of integers but not the exclusion of any other integer or group of integers. It is also noted that in this disclosure and particularly in the claims and/or paragraphs, terms such as “comprises”, “comprised”, “comprising” and the like can have the meaning attributed to it in U.S. patent law; e.g., they allow for elements not explicitly recited, but exclude elements that are found in the prior art or that affect a basic or novel characteristic of the present invention.

Furthermore, throughout the specification and claims, unless the context requires otherwise, the word “include” or variations such as “includes” or “including”, will be understood to imply the inclusion of a stated integer or group of integers but not the exclusion of any other integer or group of integers.

References in the specification to “one embodiment”, “an embodiment”, “an example embodiment”, etc., indicate that the embodiment described can include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

As used herein, terms “approximately”, “basically”, “substantially”, and “about” are used for describing and explaining a small variation. When being used in combination with an event or circumstance, the term may refer to a case in which the event or circumstance occurs precisely, and a case in which the event or circumstance occurs approximately. As used herein with respect to a given value or range, the term “about” generally means in the range of ±10%, ±5%, ±1%, or ±0.5% of the given value or range. The range may be indicated herein as from one endpoint to another endpoint or between two endpoints. Unless otherwise specified, all the ranges disclosed in the present disclosure include endpoints. When reference is made to “substantially” the same numerical value or characteristic, the term may refer to a value within ±10%, ±5%, ±1%, or ±0.5% of the average of the values.

In the methods of preparation described herein, the steps can be carried out in any order without departing from the principles of the invention, except when a temporal or operational sequence is explicitly recited. Recitation in a claim to the effect that first a step is performed, and then several other steps are subsequently performed, shall be taken to mean that the first step is performed before any of the other steps, but the other steps can be performed in any suitable sequence, unless a sequence is further recited within the other steps. For example, claim elements that recite “Step A, Step B, Step C, Step D, and Step E” shall be construed to mean step A is carried out first, step E is carried out last, and steps B, C, and D can be carried out in any sequence between steps A and E, and that the sequence still falls within the literal scope of the claimed process. A given step or sub-set of steps can also be repeated. Furthermore, specified steps can be carried out concurrently unless explicit claim language recites that they be carried out separately.

The term “polyamic acid material” refers to a polymeric precursor to polyimides, characterized by the presence of amide and carboxylic acid functional groups within its structure. It is synthesized by the reaction of diamines with dianhydrides and can serve as a passivator or additive in perovskite compositions.

The term “sacrificial carboxylic acid groups” refers to functional groups present in the polyamic acid material that are capable of forming hydrogen bonds or other interactions during processing and undergoes imidization through thermal treatment, resulting in the formation of a hydrophobic polyimide layer.

The term “hydrophobic polyimide layer” refers to a protective layer formed by the cyclization and dehydration of polyamic acid material upon thermal treatment. This layer is resistant to moisture and environmental degradation, enhancing the stability of perovskite films.

The term “perovskite precursor composition” refers to a solution comprising perovskite-forming materials, such as lead halides and organic cations, along with one or more passivators, which, upon deposition and annealing, forms a perovskite film.

The term “thermal treatment” refers to the process of heating the coated or incorporated material at a specified temperature and duration to induce imidization and the formation of a polyimide layer.

The term “power conversion efficiency (PCE)” refers to the percentage of solar energy incident on a photovoltaic device that is converted into electrical energy under standard test conditions, measured as the ratio of output electrical power to incident light power.

The term “passivation layer” refers to a surface or interfacial coating applied to a perovskite film to reduce defects, improve charge carrier dynamics, and enhance stability against environmental factors.

The term “grain boundaries” refers to the interfaces between crystalline domains in a perovskite film, which are potential sites for defects and charge recombination.

The term “charge transport layers” refers to layers in a perovskite solar cell that facilitate the movement of electrons or holes between the perovskite layer and electrodes, typically comprising materials such as SnO₂, TiO₂, or organic hole transport materials.

Other definitions for selected terms used herein may be found within the detailed description of the present invention and apply throughout. Unless otherwise defined, all other technical terms used herein have the same meaning as commonly understood to one of ordinary skill in the art to which the present invention belongs.

### REFERENCES: THE DISCLOSURES OF THE FOLLOWING REFERENCES ARE INCORPORATED BY REFERENCE

1. Yu, Y. Y., Tseng, C., Chien, W. C., Hsu, H. L., & Chen, C. P. (2019). Photovoltaic performance enhancement of perovskite solar cells using polyimide and polyamic acid as additives. The Journal of Physical Chemistry C, 123(39), 23826-23833.
2. Luo, H., Tu, F., Chen, X., Xing, L., Cao, L., Ren, G., . . . & Huo, Y. (2023). A functionalized polyamide acid additive for perovskite solar cells with high efficiency and stability. Journal of Materials Chemistry A, 11(16), 8791-8797.

What is claimed is:

1. A polyamic acid-based passivator, wherein the polyamic acid-based passivator comprises a polyamic acid material with the following formula: 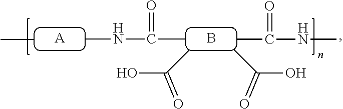
A is selected from 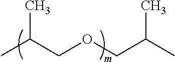
and m is in a range of 1 to 100, 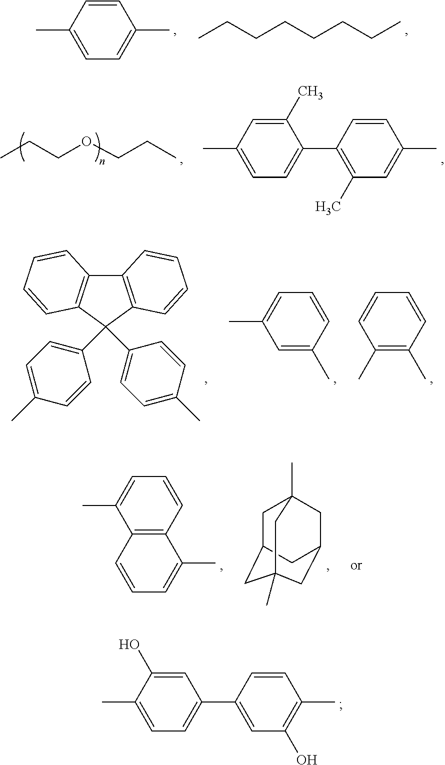
B is selected from 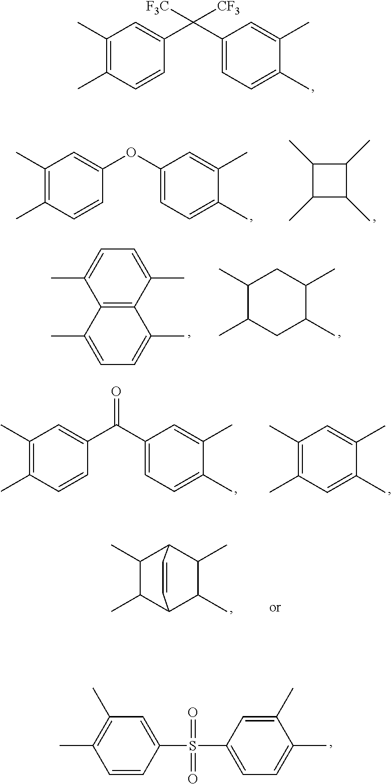
and
wherein the polyamic acid material undergoes thermal treatment to form a polyimide protective layer that enhances the stability of the perovskite.

2. The polyamic acid-based passivator of claim 1, wherein the polyamic acid material comprises polymerizing poly(propylene oxide) diamine and 4,4′-(hexafluoroisopropylidene)diphthalic anhydride.

3. The polyamic acid-based passivator of claim 1, wherein the polyamic acid material is mixed with at least one other traditional passivator selected from the group consisting of n-butylammonium acetate, di-butylammonium bromide, di-butylammonium chloride, diphenylammonium chloride, di-propylammonium chloride, di-propylammonium iodide, butane-1,4-diammonium trifluoroacetate, di-butylammonium trifluoroacetate, diphenylammonium trifluoroacetate, di-propylammonium trifluoroacetate, 2-thiopheneethylammonium chloride, dimethylammonium trifluoroacetate, 2-thiopheneethylammonium iodide, di-propylammonium bromide, 4-chlorophenethylammonium iodide, diphenylammonium iodide, diphenylammonium bromide, 2-thiopheneethylammonium bromide, 4-chloro-phenethylammonium chloride, 4-chlorophenylammonium bromide, 4-hydroxyphenethylammonium bromide, 4-hydroxyphenethylammonium iodide, 1-n-hexyl-DABCO iodide, 1-naphthylammonium bromide, 2-naphthylammonium bromide, 1-naphthylammonium chloride, 2-naphthylammonium chloride, biphenylammonium bromide, biphenylammonium iodide, 2-furanemethylammonium chloride, 2-furanemethylammonium bromide, 2-furanemethylammonium iodide, ethylammonium chloride, ethylammonium formate, 4-chlorobenzylammonium chloride, 4-methylphenethylammonium chloride, 4-chlorobenzylammonium bromide, 4-methylphenethylammonium bromide, 4-methylphenethylammonium iodide, n-butylammonium tosylate, methylammonium mesylate, ethylammonium mesylate, n-butylammonium mesylate, formamidinium mesylate, 1,4-diazabicyclo[2.2.2]octane-1,4-diium chloride, piperazine-1,4-diium chloride, morpholinium chloride, 2-pyrrolidin-1-ium-1-ylethylammonium chloride, quinuclidin-1-ium chloride, pyrrolidinium chloride, trimethylammonium bromide, N,N-diethylethane-1,2-diammonium chloride, piperazine-1,4-diium bromide, tert-octylammonium chloride, tert-octylammonium bromide, neo-pentylammonium chloride, i-pentylammonium chloride, N,N-dimethylpropane-1,3-diammonium chloride, 4-chlorophenethylammonium bromide, N,N-diethylethane-1,2-diammonium bromide, morpholinium bromide, hexane-1,6-diammonium bromide, di-iso-propylammonium bromide, 2-methoxyethylammonium bromide, 2-methoxyethylammonium chloride, di-isopropylammonium chloride, N,N-diethylpropane-1,3-diammonium chloride, 2-pyrrolidin-1-ium-1-ylethylammonium bromide, imidazolium bromide, 1,4-diazabicyclo[2,2,2]octane-1,4-diium bromide, diethylammonium bromide, morpholinium iodide, 4-fluoro-phenethylammonium chloride, n-propylammonium bromide, piperazine hydroiodide, butane-1,4-diammonium bromide, ethane-1,2-diammonium bromide, n-octylammonium Bromide, n-pentylammonium bromide, n-pentylammonium chloride, 4-fluoro-phenylammonium bromide, n-octylammonium chloride, piperazine-1,4-diium iodide, 4-trifluoromethyl-phenylammonium bromide, 4-methoxy-phenethylammonium chloride, 4-methoxy-phenylammonium iodide, 4-methoxy-phenylammonium bromide, 4-trifluoromethyl-benzylammonium iodide, guanidinium bromide, N,N-dimethylpropane-1,3-diammonium iodide, N,N-dimethylethane-1,2-diammonium iodide, n-hexylammonium bromide, 4-trifluoromethyl-phenylammonium chloride, t-butylammonium bromide, quinuclidin-1-ium bromide, 2-methoxyethylammonium iodide, tert-octylammonium iodide, neo-pentylammonium bromide, n-dodecylammonium bromide, i-pentylammonium bromide, N,N-dimethylethane-1,2-diammonium bromide, cyclohexylmethylammonium bromide, phenethylammonium iodide, 4-fluoro-phenethylammonium bromide, n-butylammonium iodide, 1,4-diazabicyclo[2,2,2]octane-1,4-diium iodide, imidazolium iodide, iso-propylammonium bromide, iso-propylammonium iodide, pyrrolidinium bromide, quinuclidin-1-ium iodide, neo-pentylammonium iodide, cyclohexylammonium bromide, 4-trifluoromethyl-benzylammonium bromide, 4-trifluoromethyl-benzylammonium chloride, 4-trifluoromethyl-phenylammonium iodide, 4-fluoro-benzylammonium chloride, 4-methoxy-phenethylammonium bromide, acetamidinium bromide, 2-pyrrolidin-1-ium-1-ylethylammonium iodide, N,N-diethylpropane-1,3-diammonium iodide, N,N-diethylpropane-1,3-diammonium bromide, 4-fluoro-phenylammonium iodide, 4-fluoro-phenylammonium chloride, di-isopropylammonium trifluoroacetate, 2-methoxyethylammonium trifluoroacetate, iso-propylammonium trifluoroacetate, hexane-1,6-diammonium chloride, di-isopropylammonium iodide, hexane-1,6-diammonium iodide, ethylammonium iodide, n-hexylammonium iodide, pyrrolidinium thiocyanate, acetamidinium iodide, hexane-1,6-diammonium trifluoroacetate, ethylammonium trifluoroacetate, 4-fluoro-benzylammonium iodide, iso-pentylammonium iodide, pyridinium iodide, cyclohexylmethylammonium iodide, n-pentylammonium iodide, n-propylammonium trifluoroacetate, n-dodecylammonium iodide, cyclohexylammonium iodide, 4-fluoro-benzylammonium bromide, dimethylammonium bromide, benzylammonium iodide, t-butylammonium iodide, benzylammonium bromide, 4-fluoro-phenethylammonium iodide, 4-methoxy-phenethylammonium iodide, n-butylammonium bromide, ethane-1,2-diammonium iodide, n-octylammonium Iodide, phenethylammonium bromide, butane-1,4-diammonium iodide, piperazine hydroiodide, or a combination thereof.

4. The polyamic acid-based passivator of claim 1, wherein the polyamic acid material further comprises an ether group that acts as a hydrogen bond acceptor.

5. A perovskite solar cell, comprising, from top to bottom:
a metal electrode layer;
an electron transport layer;
a perovskite layer comprising a perovskite precursor composition and at least one polyamic acid-based passivator, wherein the polyamic acid-based passivator contains sacrificial carboxylic acid groups and is incorporated into the perovskite precursor composition, and the perovskite precursor composition is coated onto a substrate, or optionally the polyamic acid-based passivator is deposited on one or both sides of a pristine perovskite layer;
a hole transport layer; and
a transparent conductive layer,
wherein the at least one polyamic acid-based passivator is deposited on one side or both sides of the perovskite, and the polyamic acid material interacts with the perovskite components between the sacrificial carboxylic acid groups and the perovskite, and
wherein the polyamic acid material undergoes thermal treatment to form a polyimide protective layer on the perovskite layer.

6. The perovskite solar cell of claim 5, wherein the polyamic acid material is present in the perovskite precursor composition at a concentration of 0.1-10 mg/ml.

7. The perovskite solar cell of claim 5, wherein the polyamic acid material or the polyamic acid-based passivator comprises poly(propylene oxide) diamine and 4,4′-(hexafluoroisopropylidene)diphthalic anhydride.

8. The perovskite solar cell of claim 5, wherein the passivation layer has a thickness between 0.1 nm and 25 nm.

9. The perovskite solar cell of claim 5, wherein the polyamic acid material in the at least one polyamic acid-based passivator enhances the crystallization of the perovskite layer.

10. The perovskite solar cell of claim 5, wherein the sacrificial carboxylic acid groups in the polyamic acid assist in the dispersion of the polyamic acid-based passivator.

11. The perovskite solar cell of claim 5, wherein the electron transport layer is selected from a material comprising SnO₂, TiO₂, PCBM/bathocuproine (BCP), C₆₀/bathocuproine or a mixture thereof.

12. The perovskite solar cell of claim 5, wherein the hole transport layer is selected from spiro-OMeTAD, PTAA, NiO_{X}, self-assembled monolayers, or an organic hole transport material.

13. The perovskite solar cell of claim 5, wherein the polyimide protective layer is formed after thermal treatment at a temperature of 100° C. to 150° C., enhancing the hydrophobic properties of the perovskite, and the polyimide protective layer is heat-, water- and chemical-resistant.

14. The perovskite solar cell of claim 13, wherein the thermal treatment results in the dehydration of the sacrificial carboxylic acid groups, forming a hydrophobic polyimide layer.

15. The perovskite solar cell of claim 5, wherein the perovskite solar cell achieves an improvement in power conversion efficiency of at least 23%.

16. A perovskite solar cell, comprising, from top to bottom:
a metal electrode layer;
a hole transport layer;
a perovskite layer comprising a perovskite precursor composition and at least one polyamic acid-based passivator, wherein the polyamic acid-based passivator contains sacrificial carboxylic acid groups and is incorporated into the perovskite precursor composition, and the perovskite precursor composition is coated onto a substrate, or optionally the polyamic acid-based passivator is deposited on one or both sides of a pristine perovskite layer;
an electron transport layer; and
a transparent conductive layer,
wherein the at least one polyamic acid-based passivator is deposited on one side or both sides of the perovskite, and the polyamic acid material interacts with the perovskite components between the sacrificial carboxylic acid groups and the perovskite, and
wherein the polyamic acid material undergoes thermal treatment to form a polyimide protective layer on the perovskite layer.

17. The perovskite solar cell of claim 16, wherein the polyamic acid material or the polyamic acid-based passivator comprises poly(propylene oxide) diamine and 4,4′-(hexafluoroisopropylidene)diphthalic anhydride.

18. The perovskite solar cell of claim 16, wherein the polyamic acid-based passivator is further mixed with at least one other traditional passivator selected from the group consisting of n-butylammonium acetate, di-butylammonium bromide, di-butylammonium chloride, diphenylammonium chloride, di-propylammonium chloride, di-propylammonium iodide, butane-1,4-diammonium trifluoroacetate, di-butylammonium trifluoroacetate, diphenylammonium trifluoroacetate, di-propylammonium trifluoroacetate, 2-thiopheneethylammonium chloride, dimethylammonium trifluoroacetate, 2-thiopheneethylammonium iodide, di-propylammonium bromide, 4-chlorophenethylammonium iodide, diphenylammonium iodide, diphenylammonium bromide, 2-thiopheneethylammonium bromide, 4-chloro-phenethylammonium chloride, 4-chlorophenylammonium bromide, 4-hydroxyphenethylammonium bromide, 4-hydroxyphenethylammonium iodide, 1-n-hexyl-DABCO iodide, 1-naphthylammonium bromide, 2-naphthylammonium bromide, 1-naphthylammonium chloride, 2-naphthylammonium chloride, biphenylammonium bromide, biphenylammonium iodide, 2-furanemethylammonium chloride, 2-furanemethylammonium bromide, 2-furanemethylammonium iodide, ethylammonium chloride, ethylammonium formate, 4-chlorobenzylammonium chloride, 4-methylphenethylammonium chloride, 4-chlorobenzylammonium bromide, 4-methylphenethylammonium bromide, 4-methylphenethylammonium iodide, n-butylammonium tosylate, methylammonium mesylate, ethylammonium mesylate, n-butylammonium mesylate, formamidinium mesylate, 1,4-diazabicyclo[2.2.2]octane-1,4-diium chloride, piperazine-1,4-diium chloride, morpholinium chloride, 2-pyrrolidin-1-ium-1-ylethylammonium chloride, quinuclidin-1-ium chloride, pyrrolidinium chloride, trimethylammonium bromide, N,N-diethylethane-1,2-diammonium chloride, piperazine-1,4-diium bromide, tert-octylammonium chloride, tert-octylammonium bromide, neo-pentylammonium chloride, i-pentylammonium chloride, N,N-dimethylpropane-1,3-diammonium chloride, 4-chlorophenethylammonium bromide, N,N-diethylethane-1,2-diammonium bromide, morpholinium bromide, hexane-1,6-diammonium bromide, di-iso-propylammonium bromide, 2-methoxyethylammonium bromide, 2-methoxyethylammonium chloride, di-isopropylammonium chloride, N,N-diethylpropane-1,3-diammonium chloride, 2-pyrrolidin-1-ium-1-ylethylammonium bromide, imidazolium bromide, 1,4-diazabicyclo[2,2,2]octane-1,4-diium bromide, diethylammonium bromide, morpholinium iodide, 4-fluoro-phenethylammonium chloride, n-propylammonium bromide, piperazine hydroiodide, butane-1,4-diammonium bromide, ethane-1,2-diammonium bromide, n-octylammonium Bromide, n-pentylammonium bromide, n-pentylammonium chloride, 4-fluoro-phenylammonium bromide, n-octylammonium chloride, piperazine-1,4-diium iodide, 4-trifluoromethyl-phenylammonium bromide, 4-methoxy-phenethylammonium chloride, 4-methoxy-phenylammonium iodide, 4-methoxy-phenylammonium bromide, 4-trifluoromethyl-benzylammonium iodide, guanidinium bromide, N,N-dimethylpropane-1,3-diammonium iodide, N,N-dimethylethane-1,2-diammonium iodide, n-hexylammonium bromide, 4-trifluoromethyl-phenylammonium chloride, t-butylammonium bromide, quinuclidin-1-ium bromide, 2-methoxyethylammonium iodide, tert-octylammonium iodide, neo-pentylammonium bromide, n-dodecylammonium bromide, i-pentylammonium bromide, N,N-dimethylethane-1,2-diammonium bromide, cyclohexylmethylammonium bromide, phenethylammonium iodide, 4-fluoro-phenethylammonium bromide, n-butylammonium iodide, 1,4-diazabicyclo[2,2,2]octane-1,4-diium iodide, imidazolium iodide, iso-propylammonium bromide, iso-propylammonium iodide, pyrrolidinium bromide, quinuclidin-1-ium iodide, neo-pentylammonium iodide, cyclohexylammonium bromide, 4-trifluoromethyl-benzylammonium bromide, 4-trifluoromethyl-benzylammonium chloride, 4-trifluoromethyl-phenylammonium iodide, 4-fluoro-benzylammonium chloride, 4-methoxy-phenethylammonium bromide, acetamidinium bromide, 2-pyrrolidin-1-ium-1-ylethylammonium iodide, N,N-diethylpropane-1,3-diammonium iodide, N,N-diethylpropane-1,3-diammonium bromide, 4-fluoro-phenylammonium iodide, 4-fluoro-phenylammonium chloride, di-isopropylammonium trifluoroacetate, 2-methoxyethylammonium trifluoroacetate, iso-propylammonium trifluoroacetate, hexane-1,6-diammonium chloride, di-isopropylammonium iodide, hexane-1,6-diammonium iodide, ethylammonium iodide, n-hexylammonium iodide, pyrrolidinium thiocyanate, acetamidinium iodide, hexane-1,6-diammonium trifluoroacetate, ethylammonium trifluoroacetate, 4-fluoro-benzylammonium iodide, iso-pentylammonium iodide, pyridinium iodide, cyclohexylmethylammonium iodide, n-pentylammonium iodide, n-propylammonium trifluoroacetate, n-dodecylammonium iodide, cyclohexylammonium iodide, 4-fluoro-benzylammonium bromide, dimethylammonium bromide, benzylammonium iodide, t-butylammonium iodide, benzylammonium bromide, 4-fluoro-phenethylammonium iodide, 4-methoxy-phenethylammonium iodide, n-butylammonium bromide, ethane-1,2-diammonium iodide, n-octylammonium Iodide, phenethylammonium bromide, butane-1,4-diammonium iodide, piperazine hydroiodide, or a combination thereof.
